(19) United States
(12) Patent Application Publication
(10) Pub. No.: US 2006/0267677 A1
(43) Pub. Date: Nov. 30, 2006

(54) Method and system for passband ripple cancellation in cascading filters

(75) Inventor: Yiping Fan, Fremont, CA (US)

Correspondence Address: PHILIPS ELECTRONICS NORTH AMERICA CORPORATION;INTELLECTUAL PROPERTY & STANDARDS, 1109 MCKAY DRIVE, M/S-41SJ, SAN JOSE, CA, 95131, US

(73) Assignee: Koninklijke Philips Electronics N. V.

(21) Appl. No.: 10/570,050

(22) PCT Filed: Aug. 28, 2004
(86) PCT No.: PCT/IB04/51594

§ 371 Date: Feb. 27, 2006

Related U.S. Application Data
(60) Provisional application No. 60/498,455, filed on Aug. 28, 2003.

(51) Int. Cl. H03K 5/00

(52) U.S. Cl. 327/552

(57) ABSTRACT

A composite filter (200) includes at least two cascading filters (202, 204) designed to minimize a passband ripple in the composite filter (200). The at least two cascading filters (202, 204) may also be designed to maximize stopband rejection in the composite filter (200). Filter characteristics, such as the order, bandwidth, stopband attenuation, and ripple magnitude, for the cascading filters (202, 204) are selected in order to achieve minimal passband ripple and maximum stopband rejection in the composite filter (200). The passband ripple in the composite filter (200) is minimized or cancelled by having the passband ripple in the cascading filters (202, 204) be equal or nearly equal in magnitude but out of phase with respect to each other.

The invention relates to filters, and more particularly to cascading filters. Still more particularly, the invention relates to a method and system for passband ripple cancellation in cascading filters.

Filters are used in a wide variety of applications, including communication networks such as cellular and wireless LANs. Filters are circuits that pass signals having frequencies of interest while rejecting or attenuating undesired frequencies. The range of frequencies that pass through a filter is known as the passband. The range of rejected frequencies is known as the stopband.

In an ideal filter, the magnitude response of the passband is flat and the transition region between the passband and the stopband is a perpendicular line with respect to the passband. In practice, however, there is usually a trade-off between passband flatness and the slope of the transition region. For example, the transition region is typically gradual when the magnitude response of the passband is nearly flat. But when the magnitude response of the passband is rippled (i.e. not flat), the transition region is usually abrupt or sharp. Passband ripple is undesirable in filters because it degrades signal quality by increasing signal energy in certain frequency regions and decreasing the energy in other frequency regions within the passband.

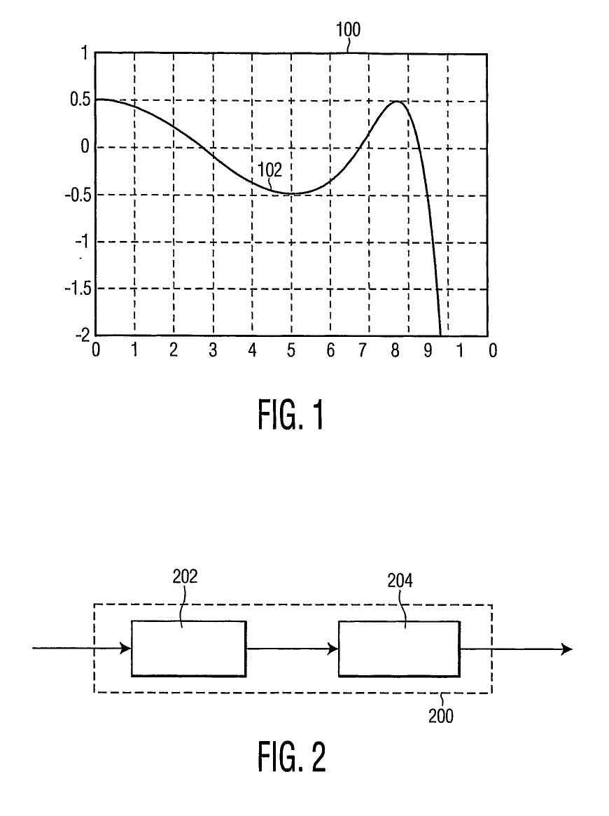

FIG. 1 is a graphical representation of a passband waveform for a filter according to the prior art. The passband ripple in waveform 102 has a magnitude of approximately one decibel. This ripple can be too great for some filter applications. And when two or more filters are connected to each other in a cascading design to create a composite filter, the passband ripples for each filter can overlap, thereby causing an increased magnitude response in the passband ripple for the composite filter.

In accordance with the invention, a method and system for passband ripple cancellation in cascading filters is provided. A composite filter design includes at least two cascading filters that minimize passband ripple in the composite filter. The at least two cascading filters may also be designed to maximize stopband rejection in the composite filter. In an exemplary embodiment in accordance with the invention, an N order filter is connected to an M order filter, where N and M are integer numbers. Filter characteristics, such as the order, bandwidth, stopband attenuation, and ripple magnitude, for the N and M order filters are selected in order to achieve minimal passband ripple and maximum stopband rejection. The passband ripple in the composite filter is minimized or cancelled by having the passband ripple in the N order filter and in the M order filter be equal or nearly equal in magnitude but out of phase with respect to each other. Composite filters in accordance with the invention may be designed with analog filters, digital filters, or with a combination of analog and digital filters, and may include any number of cascading filters.

The invention will best be understood by reference to the following detailed descriptions of illustrative embodiments in accordance with the invention when read in conjunction with the accompanying drawings, wherein:

FIG. 1 is a graphical representation of a passband waveform for a filter according to the prior art;

FIG. 2 is a block diagram of a composite filter in accordance with the invention;

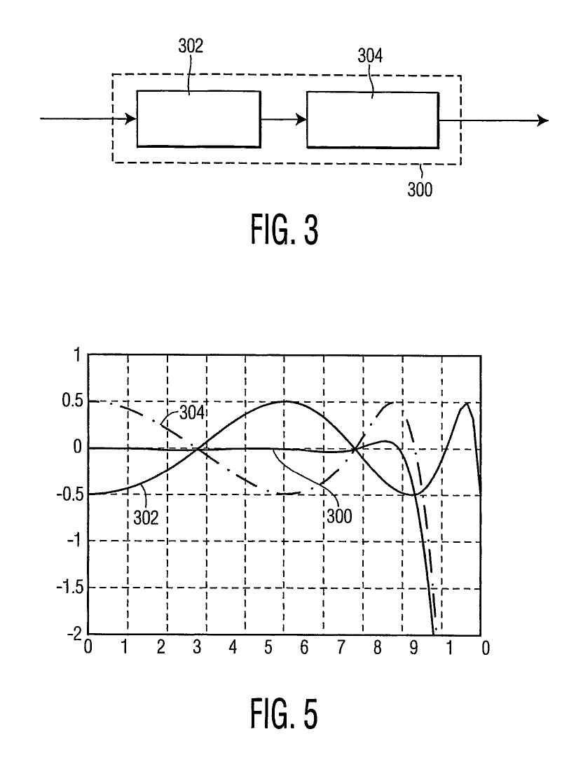

FIG. 3 is a block diagram of a composite low-pass filter in a first embodiment in accordance with the invention;

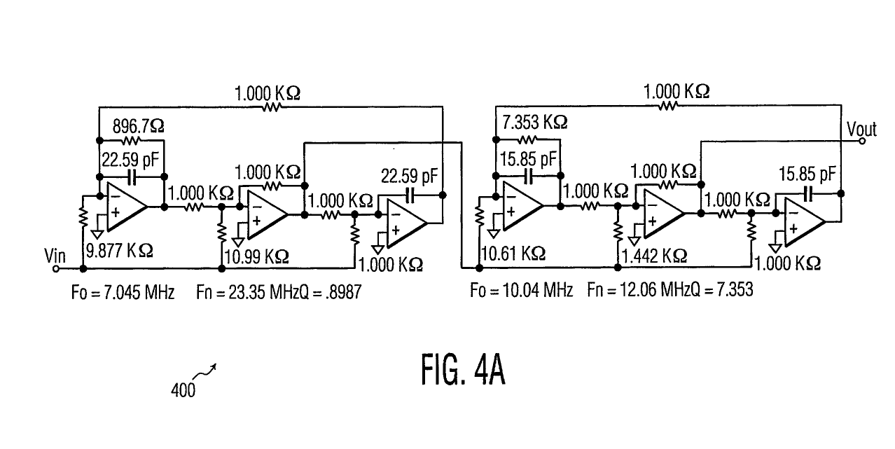

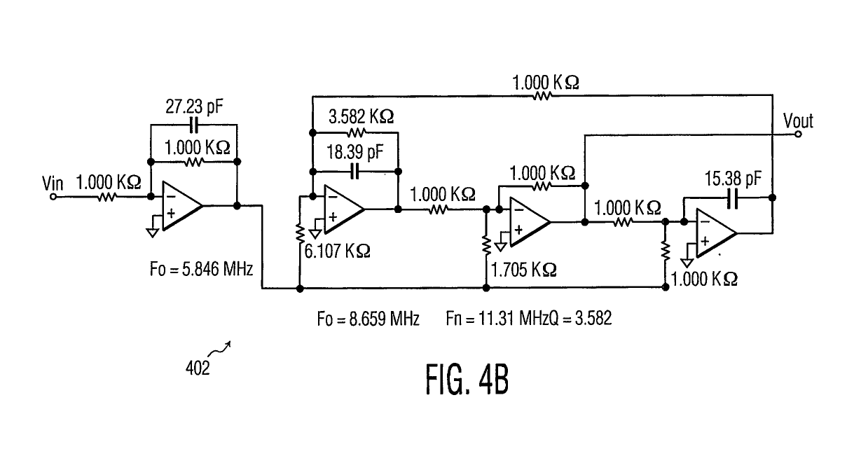

FIG. 4A is schematic diagram of a 4th order Elliptic filter that may be implemented in the composite low-pass filter of FIG. 3;

FIG. 4B is schematic diagram of a 3rd order Elliptic filter that may be implemented in the composite low-pass filter of FIG. 3;

FIG. 5 is a graphical representation of the passband waveforms for the Elliptic filters of FIGS. 4A and 4B and the composite low-pass filter of FIG. 3;

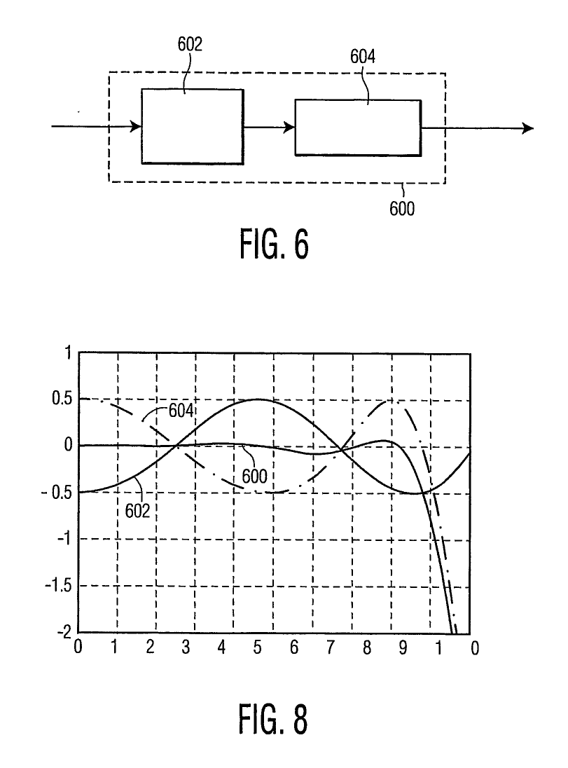

FIG. 6 is a block diagram of a composite low-pass filter in a second embodiment in accordance with the invention;

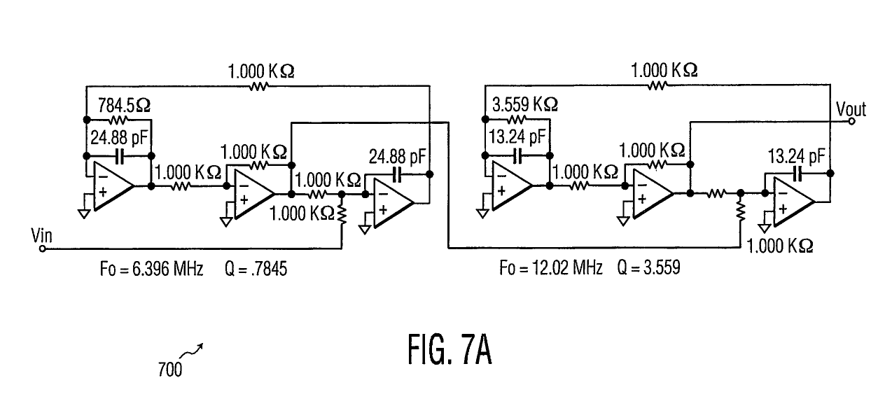

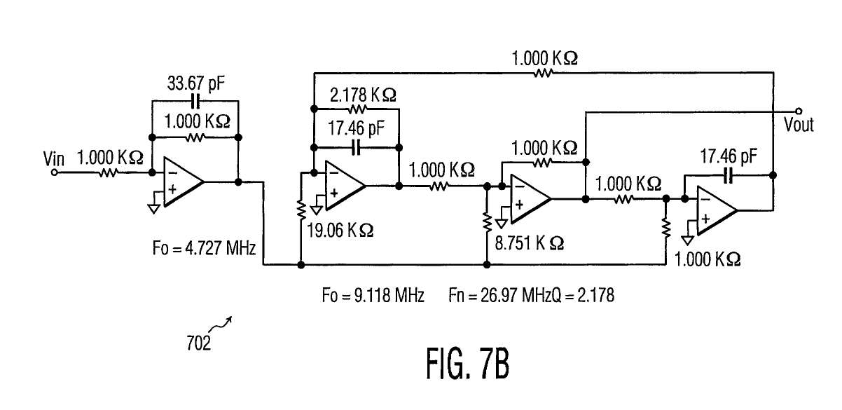

FIG. 7A is schematic diagram of a 4th order Elliptic filter that may be implemented in the composite low-pass filter of FIG. 6;

FIG. 7B is schematic diagram of a 3rd order Chebyshev filter that may be implemented in the composite low-pass filter of FIG. 6;

FIG. 8 is a graphical representation of the passband waveforms for the Chebyshev filter and the Elliptic filter of FIGS. 7A and 7B and the composite low-pass filter of FIG. 6;

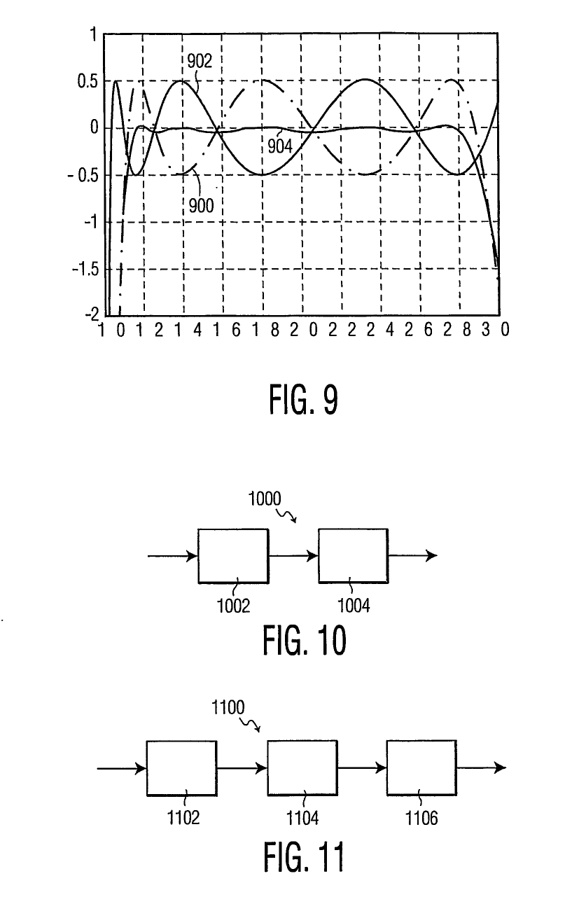

FIG. 9 is a graphical representation of the passband waveforms for a 3rd order Elliptical filter, a 4th order Elliptical filter, and a composite bandpass filter in accordance with the invention;

FIG. 10 is a block diagram of a composite digital filter in accordance with the invention; and

FIG. 11 is a block diagram of a composite filter that includes an analog filter and a digital filter in accordance with the invention.

The invention relates to a method and system for passband ripple cancellation in cascading filters. The following description is presented to enable one skilled in the art to make and use the invention, and is provided in the context of a patent application and its requirements. Various modifications to the disclosed embodiments in accordance with the invention will be readily apparent to those skilled in the art, and the generic principles herein may be applied to other embodiments in accordance with the invention. Thus, the invention is not intended to be limited to the embodiments shown, but is to be accorded the widest scope consistent with the appended claims and with the principles and features described herein.

With reference now to the figures and in particular with reference to FIG. 2, there is shown a block diagram of a composite filter in accordance with the invention. Composite filter 200 includes two cascading filters, filter 202 and filter 204. In other embodiments in accordance with the invention, additional components may be connected to the inputs-or outputs of one or both filters 202, 204. For example, an amplifier may be connected to the output of filter 202.

In the FIG. 2 embodiment, filter 202 is an N order filter and filter 204 is an M order filter, where N and M are integer numbers of one or greater. For example, filter 202 may be an even order filter and filter 204 may be an odd order filter, or vice versa. Furthermore, in the FIG. 2 embodiment, the difference between the even order and the odd order of the filters is one. Thus, filter 202 may be a 5th order filter and filter 204 a 6th order filter. In other embodiments in accordance with the invention, filters 202 and 204 can be designed as filters having any desired order.

Composite filter 200 may be implemented as an analog filter using passive components such as, for example, resistors, capacitors, and inductors, or as a digital filter using active components including, but not limited to, operational amplifiers, capacitors, and resistors. Composite filter 200 can be any class of filter, such as a low-pass or bandpass filter.

Filters 202, 204 in composite filter 200 may be implemented as any type of filter including, but not limited to, Chebyshev, Elliptic, transitional filters, and any other type of filter having a ripple in the passband. In other filter designs in accordance with the invention, more than two cascading filters may be used to construct a composite filter and any desired filter topology, such as ladder and bi-quad, may be used.

Filter characteristics, such as the order, bandwidth, stopband attenuation, and ripple magnitude, for filters 202, 204 are designed and selected in order to achieve minimal passband ripple and maximum stopband rejection in composite filter 200. The passband ripple in composite filter 200 is minimized or cancelled by having the passband ripple in filter 202 and in filter 204 be equal, or nearly equal, in magnitude but out of phase (partially or completely) with respect to each other.

FIG. 3 is a block diagram of a composite low-pass filter in a first embodiment in accordance with the invention. Composite low-pass filter 300 is a 7th order low-pass filter that includes a 4th order Elliptic filter 302 connected to a 3rd order Elliptic filter 304 in this embodiment in accordance with the invention. FIG. 4A. is schematic diagram of a 4th order Elliptic filter that may be implemented in the composite low-pass filter of FIG. 3. FIG. 4B is schematic diagram of a 3rd order Elliptic filter that may be implemented in the composite low-pass filter of FIG. 3. In other embodiments in accordance with the invention, the Elliptic filters may be implemented with components and component values other than those shown in FIG. 4A and FIG. 4B. Furthermore, the order of the filters may be reversed, i.e., with a 3rd order Elliptic filter placed before a 4th order Elliptic filter, in other embodiments in accordance with the invention.

Filter characteristics, such as the order, bandwidth, stopband attenuation, and ripple magnitude, for the 4th order Elliptic filter 302 and the 3rd order Elliptic filter 304 are designed and selected to achieve minimal passband ripple and maximum stopband rejection in the low-pass filter 300. Table 1 lists the characteristics for each filter 302, 304:

TABLE 1
Filter Characteristics

| Filter | Type | Order | Bandwidth | Ripple | Stopband Attenuation |
|---|---|---|---|---|---|
| 302 | Elliptic | 4 | 10 MHz | 1 dB | 24 dB |
| 304 | Elliptic | 3 | 8.5 MHz | 1 dB | 17 dB |

Referring to FIG. 5, there is shown a graphical representation of the passband waveforms for the Elliptic filters of FIGS. 4A and 4B and the composite low-pass filter of FIG. 3. Elliptic filter 302 has a one-decibel passband ripple, and elliptic filter 304 also has a one-decibel passband ripple. Thus, the magnitudes of the two passband ripples are equal (or nearly equal). The two waveforms, however, are out of phase with respect to each other. Consequently, their cumulative effect is to minimize the passband ripple in the waveform for the composite low-pass filter 300. The combined frequency response is relatively flat with a peak ripple less than 0.1 dB at approximately 7.6 MHz. Additionally, the transition from the passband to the stopband is relatively sharp, thereby providing a relatively high degree of stopband rejection.

FIG. 6 is a block diagram of a composite low-pass filter in a second embodiment in accordance with the invention. Composite low-pass filter 600 is a 7th order low-pass filter that includes a 4th order Chebyshev filter 602 connected to a 3rd order Elliptic filter 604 in this embodiment in accordance with the invention. FIG. 7A is schematic diagram of a 4th order Elliptic filter that may be implemented in the composite low-pass filter of FIG. 6. FIG. 7B is schematic diagram of a 3rd order Chebyshev filter that may be implemented in the composite low-pass filter of FIG. 6. In other embodiments in accordance with the invention, the Elliptic and Chebyshev filters may be implemented with components and component values other than those shown in FIG. 7A and FIG. 7B. Furthermore, the order of the filters may be reversed, i.e., with an Elliptic filter placed before a Chebyshev filter, in other embodiments in accordance with the invention.

Filter characteristics, such as the order, bandwidth, stopband attenuation, and ripple magnitude, for the 4th order Chebyshev filter 602 and the 3rd order Elliptic filter 604 are designed and selected to achieve minimal passband ripple and maximum stopband rejection in the low-pass filter 600. Table 2 lists the characteristics for each filter 602, 604:

TABLE 2
Filter Characteristics

| Filter | Type | Order | Bandwidth | Ripple | Stopband Attenuation |
|---|---|---|---|---|---|
| 602 | Chebyshev | 4 | 12.1 MHz | 1 dB | NA |
| 604 | Elliptic | 3 | 9.1 MHz | 1 dB | 32 dB |

Referring to FIG. 8, there is shown a graphical representation of the passband waveforms for the Chebyshev filter and the Elliptic filter of FIGS. 7A and 7B and the composite low-pass filter of FIG. 6. Both the Chebyshev filter 602 and the Elliptic filter 604 have a one-decibel passband ripple. Thus, the magnitudes of the two passband ripples are equal (or nearly equal). The two waveforms, however, are out of phase with respect to each other. Consequently, their cumulative effect is to minimize the passband ripple in the waveform for the composite low-pass filter 600. The combined frequency response is relatively flat with a peak ripple less than 0.10 dB at approximately 7.8 MHz. Additionally, the transition from the passband to the stopband is relatively sharp, thereby providing a relatively high degree of stopband rejection.

FIG. 9 is a graphical representation of the passband waveforms for a 3rd order Elliptical filter, a 4th order Elliptical filter, and a composite bandpass filter in accordance with the invention. A bandpass filter that can generate waveform 904 includes two cascading filters that are each first designed as low-pass filters in this embodiment in accordance with the invention. A conventional low-pass to bandpass transformation is then performed. In the FIG. 9 embodiment, the desired center frequency of the bandpass filter is 20 MHz, while the center frequency used for the transformation is 18 MHz. Table 3 lists the characteristics for each low-pass filter:

TABLE 3
Filter Characteristics

| Filter | | | | | Stopband |
|---|---|---|---|---|---|
| (waveform) | Type | Order | Bandwidth | Ripple | Attenuation |
| 900 | Elliptic | 3 | 9.1 MHz | 1 dB | 37 dB |
| 902 | Elliptic | 4 | 10.6 MHz | 1 dB | 35 dB |

As shown in FIG. 9, both low-pass filters have a one-decibel ripple in their passbands (see waveforms 900, 902). The two waveforms 900, 902 however, are out of phase with respect to each other. Thus, their cumulative effect is to minimize the passband ripple in the composite bandpass filter (see waveform 904). The combined frequency response is relatively flat and the transition from the passband to the stopband is relatively sharp, thereby providing a relatively high degree of stopband rejection.

Referring to FIG. 10, there is shown a block diagram of a composite digital filter in accordance with the invention. Composite digital filter 1000 includes two cascaded digital filters 1002, 1004. Filter 1002 and filter 1004 may be implemented as an infinite impulse response (IIR) type digital filter or as a finite impulse response (FIR) type digital filter. Those skilled in the art will appreciate that filter order, as used in conjunction with analog filters, is not a design consideration for FIR type digital filters.

As with the analog filters, filter characteristics such as the bandwidth, stopband attenuation, ripple magnitude, and order (for IIR type filters), for filters 1002, 1004 are designed and selected in order to achieve minimal passband ripple and maximum stopband rejection in composite filter 1000. The passband ripple in composite digital filter 1000 is minimized or cancelled by having the passband ripple in the filter 1002 and in the filter 1004 be equal, or nearly equal, in magnitude but out of phase (partially or completely) with respect to each other.

FIG. 11 is a block diagram of a composite hybrid filter that includes an analog filter and a digital filter in accordance with the invention. Composite hybrid filter 1100 includes, but is not limited to, an analog filter 1102, an analog to digital (ADC) converter 1104, and a digital filter 1106. The positioning of the filters 1102, 1106 may be reversed, i.e., with the digital filter 1106 placed before the analog filter 1102 with a digital to analog (DAC) converter between the two filters.

Filter characteristics such as the order, bandwidth, stopband attenuation, and ripple magnitude, for filters 1102, 1104 are designed and selected in order to achieve minimal passband ripple and maximum stopband rejection in composite hybrid filter 1100. The passband ripple in composite hybrid filter 1100 is minimized or cancelled by having the passband ripple in filter 1102 and in filter 1104 be equal, or nearly equal, in magnitude but out of phase (partially or completely) with respect to each other.

Embodiments in accordance with the invention, however, are not limited to composite filter designs having only two cascading filters. A composite analog filter, a composite digital filter, and a composite hybrid filter can be designed and implemented with any desired number of cascading filters in accordance with the invention.

1. A composite filter comprising at least two cascading filters having passband ripples nearly equal in magnitude and out of phase with respect to each other in order to minimize a passband ripple in the composite filter.

2. A composite filter as claimed in claim 1, characterized in that the magnitude of the passband ripples in the at least two cascading filters are equal.

3. A composite filter as claimed in claim 1, characterized in that at least one of the at least two cascading filters comprises a digital filter.

4. A composite filter as claimed in claim 1, characterized in that at least one of the at least two cascading filters comprises an analog filter.

5. A composite filter as claimed in claim 1, characterized in that at least one characteristic of the at least two cascading filters (202, 204) is selected to minimize the passband ripple in the composite filter.

6. A composite filter as claimed in claim 5, characterized in that the at least one characteristic comprises the order of the at least two cascading filters.

7. A composite filter as claimed in claim 6, characterized in that at least one filter is an even order filter and at least one filter is an odd order filter.

8. A composite filter as claimed in claim 7, characterized in that the even order and the odd order differ in value by one.

9. A composite filter as claimed in claim 5, characterized in that the at least one characteristic comprises a bandwidth of the at least two cascading filters.

10. A composite filter as claimed in claim 5, characterized in that the at least one characteristic comprises a stopband attenuation of the at least two cascading filters.

11. A method for passband ripple cancellation in cascading filters to minimize a passband ripple in a composite filter comprising the steps of: providing at least two filters having passband ripples nearly equal in magnitude and out of phase with respect to each other in order to minimize the passband ripple in the composite filter.

12. A method as claimed in claim 11, characterized in that the magnitudes of the passband ripples in the at least two cascading filters are equal.

13. A method as claimed in claim 11, characterized in that at least one of the at least two cascading filters comprises a digital filter.

14. A method as claimed in claim 11, characterized in that at least one of the at least two cascading filters comprises an analog filter

15. A method as claimed in claim 11, characterized in that at least one filter characteristic for the at least two cascading filters is selected to minimize the passband ripple in the composite filter.

16. A method as claimed in claim 15, characterized in that the at least one filter characteristic includes a bandwidth for the at least two cascading filters.

17. A method as claimed in claim 15, characterized in that the at least one filter characteristic includes a stopband attenuation for the at least two cascading filters.

18. A method as claimed in claim 15, characterized in that the at least one filter characteristic includes an order for the at least two cascading filters.

19. A method as claimed in claim 18, characterized in that at least one of the at least two cascading filters has an even order and at least one of the at least two cascading filters has an odd order.

20. A method as claimed in claim 19, characterized in that the even and the odd orders differ in value by one.
